(19) United States
(12) Patent Application Publication
(10) Pub. No.: US 2024/0421191 A1
(43) Pub. Date: Dec. 19, 2024

(54) FUNNELED SOURCE/DRAIN INTERFACIAL REGION

(71) Applicant: INTERNATIONAL BUSINESS MACHINES CORPORATION, ARMONK, NY (US)

(72) Inventors: Shogo Mochizuki, Mechanicville, NY (US); Erin Stuckert, Albany, NY (US)

(21) Appl. No.: 18/335,691

(22) Filed: Jun. 15, 2023

(51) Int. Cl. H01L 29/08; H01L 21/8238; H01L 27/092; H01L 29/06; H01L 29/423; H01L 29/66; H01L 29/775; H01L 29/786

(52) U.S. Cl. CPC H01L 29/0847; H01L 21/823814; H01L 27/092; H01L 29/0673; H01L 29/42392; H01L 29/66439; H01L 29/66545; H01L 29/775; H01L 29/78696

(57) ABSTRACT

A transistor includes a funneled interfacial source/drain (S/D) region that includes a narrow throat that is connected to or is an interface to the nanolayer channel. The funneled interfacial S/D region may also include a wide throat that is an interface to a remainder of the S/D region. The funneled interfacial source/drain (S/D) region may reduce parasitic resistance or impedance from the S/D region into or out of a nanolayer channel.

### BACKGROUND

The present disclosure relates to fabrication methods and resulting structures for semiconductor devices. More specifically, the present disclosure relates to fabrication methods and resulting semiconductor integrated circuit (IC) devices that include a transistor with a funneled source/drain region that interfaces to a nanolayer channel.

Conventional transistors, such semiconductor IC devices, or the like, incorporate planar field effect transistors (FETs) in which current flows through a semiconducting channel between a source and a drain, in response to a voltage applied to a control gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanosheets, or the like, that are isolated from the substrate. In the GAA FET, channel surfaces are in respective contact with the source and drain and other respective channel surfaces are in contact with and surrounded by the gate.

### SUMMARY

In an embodiment of the present disclosure, a transistor is presented. The transistor includes a gate around a channel, a top funneling inner spacer directly upon a top surface of the channel, and a source/drain (S/D) region directly upon the first funneling inner spacer. The S/D region includes a funneled interfacial region that includes a wide throat and a narrow throat that is directly upon an end surface of the channel. The funneled interfacial region may reduce parasitic resistance or impedance from the S/D region into or out of the channel.

In an example, the wide throat is an integral interface between the funneled interfacial region and a remainder of the S/D region. In other words, the wide throat is a part of or integral to the remainder of the S/D region and there is limited interfacial resistance between the funneled interfacial region and the remainder of the S/D region.

In an example, the top funneling inner spacer includes a first receded non-orthogonal corner between a bottom surface of the top funneling inner spacer and an outer sidewall of the top funneling inner spacer. In this way, the first receded non-orthogonal corner of the top funneling inner spacer forms or creates a partial funneling shape of the funneled interfacial region.

In examples, the first receded non-orthogonal corner is chamfered, filleted, or non-linear. The various shapes of the first receded non-orthogonal corner may result from or are influenced by the type of subtractive removal technique (e.g., etching) chosen to recess an exposed and substantially coplanar corner to form the funneling inner spacer.

In an example, the first receded non-orthogonal corner has a positive slope. The positive slope results from the orientation of the funneled interfacial region being positioned with the narrow throat being an interface to the channel and the wide throat being an integral interface to the remainder of the S/D region.

In an example, the end surface of the channel is inset between the outer sidewall of the funneling inner spacer and an inner sidewall of the funneling inner spacer. The end surface of the channel being inset within the funneling inner spacer is a result of indenting the channel to expose an external corner region of the inner spacer which is later recessed to form the funneling inner spacer.

In an example, the end surface of the channel is concave. The concave end surface of the channel is a result of a particular substrative removal technique (e.g., lateral etch, or the like) used to indent the channel and may also advantageously increase a volume of the funneled interfacial region.

In an example, the transistor also includes a bottom funneling inner spacer directly upon a bottom surface of the channel. In this way, the funneled interfacial region may be symmetrical across a substantially horizontal bisector which may also increase the volume of the funneled interfacial region.

In an example, the bottom funneling inner spacer includes a second receded non-orthogonal corner between a top surface of the bottom funneling inner spacer and an outer sidewall of the bottom funneling inner spacer. In this way, the second receded non-orthogonal corner of the bottom funneling inner spacer along with the first receded non-orthogonal corner of the top funneling inner spacer forms or creates the funneling shape of the funneled interfacial region.

In an example, the receded non-orthogonal corner has a negative slope. The negative slope results from the orientation of the funneled interfacial region being positioned with the narrow throat being an interface to the channel and the wide throat being an integral interface to the remainder of the S/D region.

In another embodiment of the present disclosure, a transistor is presented. The transistor includes a gate around a channel and a source/drain (S/D) region directly upon the first funneling inner spacer. The S/D region includes a funneled interfacial region that includes a wide throat and a narrow throat that is directly upon an end surface of the channel. The funneled interfacial region may reduce parasitic resistance or impedance from the S/D region into or out of the channel.

In an example, the wide throat is an integral interface between the funneled interfacial region and a remainder of the S/D region. In other words, the wide throat is a part of or integral to the remainder of the S/D region and limited interfacial resistance exists between the funneled interfacial region and the remainder of the S/D region.

In an example, the wide throat has a larger circumference relative to the narrow throat. The relative circumferential difference between the wide throat and the narrow throat forms the funneling shape of the funneled interfacial region.

In examples, a linear surface, a rounded surface, or a non-linear surface connects the narrow throat and the wide throat. The various surface shapes may result from or are influenced by a geometry of prefabricated structures (e.g., funneling inner spacer) that which the funneled interfacial region is formed upon and resultantly takes the shape thereof.

In another embodiment of the present disclosure a method to fabricate a semiconductor integrated circuit (IC) device is presented. The method includes forming an inner spacer directly upon an active nanolayer. The method further includes after forming the inner spacer, indenting the active nanolayer and exposing an external corner region of the inner spacer. The method further includes recessing the external corner region of the inner spacer to form a funneling inner spacer. The method allows for a funneling void or pocket to be formed by the funneling inner spacer in relation to the active nanolayer.

In an example, the method further includes forming a source/drain (S/D) region directly upon the funneling inner spacer. The void is therefore filled with source or drain material(s) to form a funneled interfacial region which takes the shape of the void. The funneled interfacial region may reduce parasitic resistance or impedance from the S/D region into or out of the active nanolayer.

The above summary is not intended to describe each illustrated embodiment or every implementation or example of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts a semiconductor IC device that includes a funneled source/drain region that interfaces to a nanolayer channel, according to one or more embodiments of the disclosure.

FIG. 2 through FIG. 13 depict various fabrication structure views of an exemplary semiconductor IC device that includes a funneled source/drain region that interfaces to a nanolayer channel, according to one or more embodiments of the disclosure.

FIG. 14 through FIG. 16 depict illustrative funneled source/drain regions that interface to a nanolayer channel, according to one or more embodiments of the disclosure.

FIG. 17 depict a method of fabricating a semiconductor IC device that includes a funneled source/drain region that interfaces to a nanolayer channel, according to one or more embodiments of the disclosure.

### DETAILED DESCRIPTION

The present disclosure describes an illustrative semiconductor IC device that includes transistor, such as a GAA transistor, with one or more funneling inner spacers located between vertically stacked channels. There are many different types of transistors, such as but not limited to FinFETs, GAA FETs, fork sheet FETs, and the like. Though illustrative GAA FETs are depicted in the drawings, embodiments of the present disclosure should not be limited thereto and may be applied to other transistors that include one or more funneled source/drain regions that interface to a nanolayer channel.

The flowcharts and cross-sectional diagrams in the drawings illustrate a method of fabricating semiconductor IC device, such as a processor, FPGA, memory module, or the like. In some alternative implementations, the fabrication steps may occur in a different order that that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The semiconductor IC devices disclosed herein may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of +8%, +5%, +2%, or the like, difference between the coplanar materials.

As used herein, the term “coplanar” refers to two surfaces that lie in a common plane. In other words, two surfaces are coplanar if there exists a geometric plane that contains all of the points of both of the surfaces. As used herein, the term “substantially” refers to an extent to which minor deviations are included such that the deviations do not impact the desired result. Accordingly, two surfaces may be referred to as substantially coplanar despite deviations from coplanarity on an atomic scale, so long as those deviations do not impact the desired result of the coplanarity.”

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor device and IC fabrication may or may not be described in detail herein. Moreover, the various tasks and process steps described herein can be incorporated into a more comprehensive procedure or process having additional steps or functionality not described in detail herein. Various steps in the manufacture of semiconductor devices are well known and so, in the interest of brevity, many conventional steps will only be mentioned briefly herein or will be omitted entirely without providing the well-known process details.

In general, the various processes used to form a microchip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of an FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanosheet, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for superior channel electrostatics control, which is necessary for continuously scaling gate lengths.

In certain semiconductor IC devices, a parasitic resistance (e.g., interfacial resistance, or the like) exists between a source and/or drain region and the active nanolayer due to a relatively small junction between the source and/or drain region and the active nanolayer channel. Embodiments of the disclosure provide for a funneling inner spacer located between the active nanolayer channels. The funneled shape of the funneling inner spacer increases the junction thickness of the source and/or drain region within the interfacial region between the active nanolayer and the source and/or drain region and resultingly and advantageously may decreases the parasitic resistance therebetween.

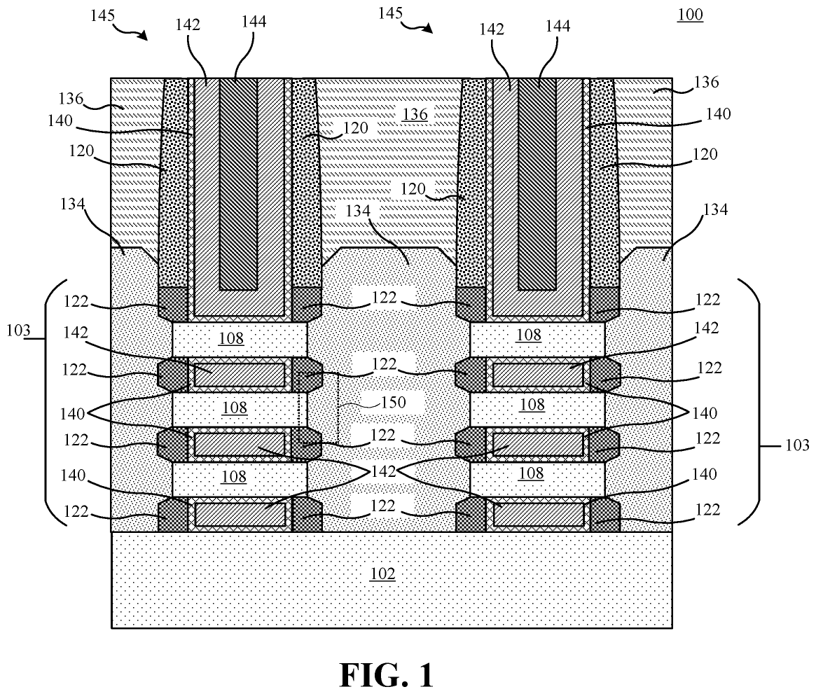

Referring now to the drawings in which like numerals represent the same or similar elements and initially to FIG. 1, this figure depicts a cross-sectional view of a semiconductor IC device 100 that include one or more funneling inner spacers 122 and one or more source/drain (S/D) regions 134, according to embodiments. The funneling inner spacer(s) 122 may be located between vertically stacked active nanolayers 108 which serve as the channel between the S/D regions 134. The funneled shape of the funneling inner spacer 122 increases a junction thickness of the S/D regions 134 within an interfacial region between the active nanolayers 108 and the S/D regions 134 and resultingly and advantageously may decreases a parasitic resistance therebetween.

In other words, the shape of the funneling inner spacer 122 creates a funneled interfacial region within the S/D regions 134 which may reduce resistance or impedance within the interfacial region between the active nanolayer(s) 108 and the remaining S/D region 134. On one side, the funneled interfacial region may be defined by a planar cross-sectional area within the S/D region 134 that is coplanar with an outer side surface or outermost surface point of the funneling inner spacer 122 there above or there below and may be referred to herein as the large circumference of the funneled interfacial region. On a side opposite or distal relative to the large circumference of the funneled interfacial region, the funneled interfacial region may be defined by a planar cross-sectional area within the S/D region 134 that is juxtaposed against an end surface of the associated active nanolayer 108 and may be referred to herein as the small circumference of the funneled interfacial region. The end surface of this active nanolayer 108 may be between the sidewalls of the funneling inner spacers 122 there above and there below. In other words, the end surface of this active nanolayer 108 may be inset within the funneling inner spacers 122 there above and there below. The end surface of the active nanolayer 108 may be substantially vertical, concave, or the like.

Due to the funneling inner spacer 122, the large circumference of the funneled interfacial region has a larger circumference, cross-sectional area, or the like, relative to the small circumference of the funneled interfacial region, and thereby forms the funneled shape of the funneled interfacial region within the S/D region 134. The small circumference of the funneled interfacial region (which may also be referred herein as the narrow throat of the funneled interfacial region) is adjacent and/or directly upon the end surface of the active nanosheet. The large circumference of the funneled interfacial region (which may also be referred herein as the wide throat of the funneled interfacial region) may be coplanar with respective sidewall(s) of the funneling inner spacer(s) 122 there above and/or there below. The term “throat” herein is synonymous with a passage, entrance, exit, or the like for electrical current into or out of S/D region 134 to or from a channel (i.e., active nanolayer 108).

One or more surfaces connect the wide throat to the narrow throat. These one or more may be juxtaposed directly against respective receded non-orthogonal corners that give the funneling inner spacer(s) the funneling shape. The one or more surfaces may be linear (e.g., one or more chamfered surface(s) that connect the wide throat with the narrow throat), may be arced (e.g., one or more filleted surface(s) that connect the wide throat with the narrow throat), and/or may be non-linear (e.g., one or more non-linear surface(s) that connect the wide throat with the narrow throat).

In the depicted example, a S/D region 134 may have multiple funneled interfacial regions therewithin with each funneled interfacial region being associated with a different active nanolayer 108. In particular, the S/D region 134 may be located between neighboring replacement gate structures 145 and may have multiple funneled interfacial regions, each being associated with one active nanolayer 108. A first series of active nanolayers 108 are vertically in line with one another and a first replacement gate structure 145, of the neighboring replacement gate structures 145, wraps around the first series of active nanolayers 108. A second series of active nanolayers 108 are vertically in line with one another and a second replacement gate structure 145, of the neighboring replacement gate structures 145, wraps around the second series of active nanolayers 108. The first series of active nanolayers 108 are associated with a first series of vertically inline funneled inner spacers 122 that juxtaposed against and/or that form a first series of vertically inline funneled interfacial regions. The second series of active nanolayers 108 are associated with a second series of vertically inline funneled inner spacers 122 that juxtaposed against and/or that form a second series of vertically inline funneled interfacial regions.

In an illustrated example, the semiconductor IC device 100 may include one or more GAA FETs. The GAA FETs provide a relatively small FET footprint by arranging the channel as vertically stacked active nanolayers 108. In an illustrated GAA configuration, the GAA FET includes a source region (a first S/D region 134), a drain region (a first S/D region 134), and vertically stacked active nanolayers 108 between the source and drain regions. The replacement gate structure 145 surrounds the vertically stacked active nanolayers 108 and regulates electron flow through the vertically stacked active nanolayers 108 between the S/D regions 134.

For n-type GAA FETs, the active nanolayers 108 may be silicon (Si). For p-type GAA FETs, the active nanolayers 108 can be SiGe or Si. Forming active nanolayers 108 from SiGe or Si, depending upon the transistor type, may provide for superior channel electrostatics control, which is beneficial for continuously scaling gate lengths.

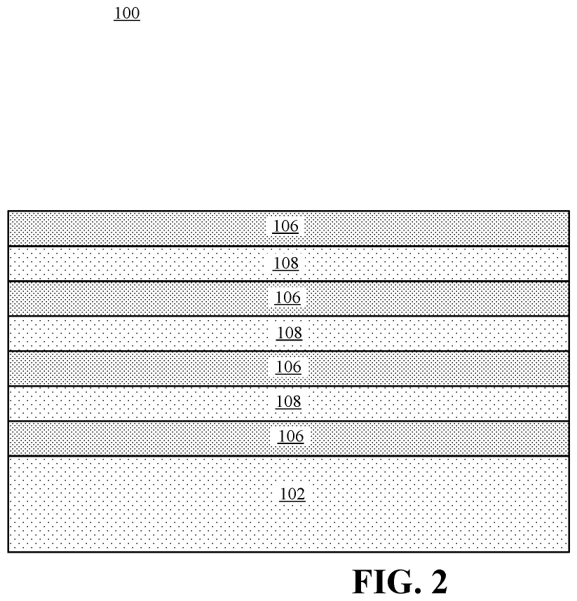

In the illustrated example, semiconductor IC device 100 may further include a substrate structure 102, one or more replacement gate structures 145, gate spacers 120, and/or interlayer dielectric (ILD) 136. The replacement gate structure 145 may include a high-k layer 140, a work function gate 142, and a conductive fill gate 144. The vertically stacked active nanolayers 108 may be arranged within a nanolayer stack 103, the formation of which in association with the fabrication of IC device 100 are described below with reference to FIG. 2 through FIG. 13.

For clarity, FIG. 1 also depicts a region 150 that is enlarged in subsequent figures.

FIG. 2 depicts a cross-sectional view of the semiconductor IC device 100 after initial fabrication operations, in accordance with embodiments of the present disclosure. In these initial fabrication stages, nanolayers are formed upon a substrate structure 102.

The substrate structure 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon (Si) is the predominantly used semiconductor material in wafer fabrication, alternative semiconductor materials can be employed, such as, but not limited to, gallium arsenide, gallium nitride, cadmium telluride, zinc selenide, and III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements. In another implementation, the substrate structure 102 includes an upper substrate, a lower substrate, and an insulator layer between the upper substrate and the lower substrate. The upper and lower substrates may be comprised of any other suitable material(s) that those listed above and the insulator layer may be a dielectric layer, such as an oxide, and may be referred to as a buried oxide (BOX) substrate. In another implementation, the substrate structure 102 includes an upper substrate, a lower substrate, and an etch stop layer between the upper substrate and the lower substrate. The etch stop layer may be a dielectric layer may be any dielectric with etch selectivity to one or both of the upper substrate and/or the lower substrate.

Nanolayers may be formed upon the substrate structure 102 by forming alternating blanket layers of sacrificial nanolayers 106 and active nanolayers 108. In certain examples, the first one of the sacrificial nanolayers 106 is initially formed directly on an upper surface of the substrate structure 102. In other examples, certain layers may be formed between the upper surface of the substrate structure 102 and the first one of the sacrificial nanolayers 106. In an example, each sacrificial nanolayers 106 is composed of silicon-germanium (e.g., SiGe, where the Ge ranges from about 25-40%). Next, a blanket layer of the active nanolayer 108 is formed on an upper surface of the first one of the sacrificial nanolayers 106. In an example, the active nanolayer 108 is composed of silicon. Several additional blanket layers of the sacrificial nanolayers 106 and active nanolayers 108 are alternately formed. In the illustrated semiconductor IC device 100, there are a total of four sacrificial nanolayers 106 and three active nanolayers 108. However, it should be appreciated that any suitable number of alternating layers may be formed.

Although it is specifically contemplated that the blanket sacrificial nanolayers 106 can be formed from SiGe and that the blanket active nanolayers 108 can be formed from Si, it should be understood that any appropriate materials can be used instead, as long as the two semiconductor materials have etch selectivity with respect to one another.

The alternating blanket nanolayers can be deposited by any appropriate mechanism. The alternating blanket nanolayers can be epitaxially grown from one another, but alternate deposition processes, such as chemical vapor deposition (CVD), physical vapor deposition (PVD), atomic layer deposition (ALD), or gas cluster ion beam (GCIB) deposition, are also contemplated.

In certain embodiments, the blanket sacrificial nanolayers 106 have a vertical thickness ranging, for example, from approximately 3 nm to approximately 20 nm. In certain embodiments, the sacrificial nanolayers 106 and active nanolayers 108 have a vertical thickness ranging, for example, from approximately 3 nm to approximately 10 nm. Although seven total sacrificial nanolayers 106 and active nanolayers 108 are depicted in semiconductor IC device 100, it should be appreciated that the any suitable number of layers may be utilized. Although the range of 3-20 nm is cited as an example range of thickness of the sacrificial nanolayers 106 and active nanolayers 108, other thickness of these nanolayers may be used. In certain examples, certain of the sacrificial nanolayers 106 and active nanolayers 108 may have different thicknesses relative to one another. For example, multiple epitaxial growth processes can be performed to form the alternating the sacrificial nanolayers 106 and active nanolayers 108.

In certain embodiments, it may be desirable to have a small vertical spacing (VSP) between adjacent active nanolayers 108 in a stack of nanolayers to reduce the parasitic capacitance and to improve circuit speed. For example, the VSP (the distance between the bottom surface of a first active nanolayer 108 and the top surface of an adjacent active nanolayer 108) may range from 5 nm to 15 nm. However, the VSP must be of a sufficient value to accommodate the gate that will be formed in the spaces created by later removal of respective portions of the sacrificial nanolayers 106.

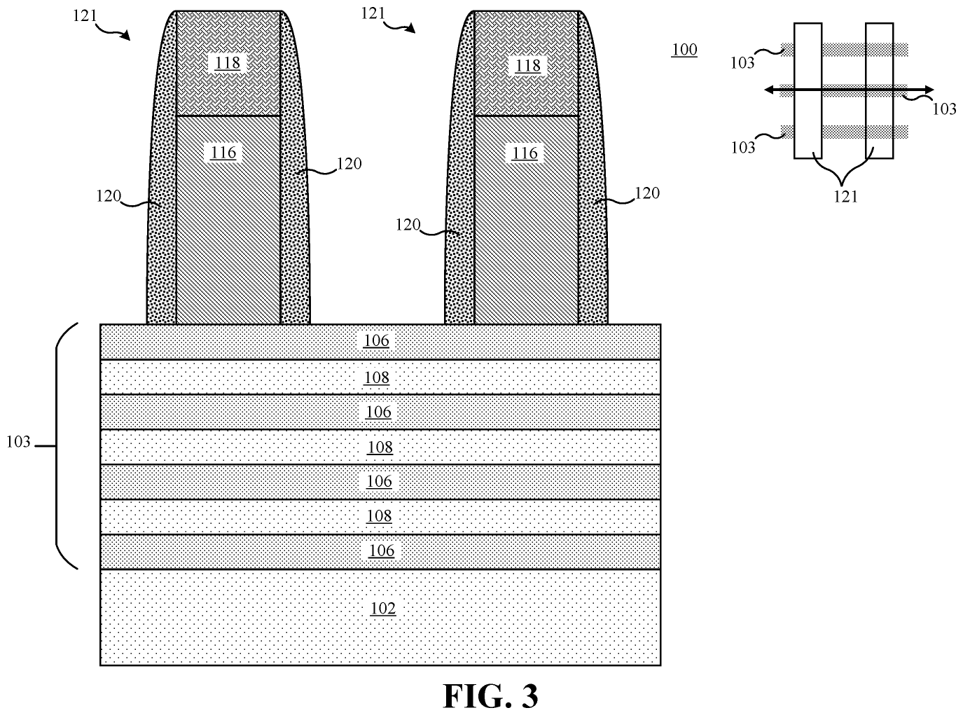

FIG. 3 depicts a cross-sectional view of the semiconductor IC device 100 after fabrication operations, in accordance with embodiments of the present disclosure. In the depicted fabrication stages, the nanolayers are patterned into nanolayer stacks 103, sacrificial gate structures 121 are formed, and gate spacers 120 are formed. For clarity, also depicted in FIG. 3 is a top-down view of multiple nanolayer stacks 103 and multiple sacrificial gate structures 121 and a plane upon which the cross-sectional views of the drawings are established.

To form one or more nanolayer stacks 103, a mask layer (not shown) is formed on the uppermost nanolayer. The mask layer may be comprised of any suitable material(s) known to one of skill in the art. The mask layer may be patterned and used to perform the nanolayer stack 103 patterning process. In the nanolayer stack 103 patterning process, any suitable material removal process (e.g., reactive ion etching or RIE) may be used to remove portions of the alternating nanolayers down to the level of the substrate structure 102, down to the insulator layer within the substrate structure, or the like. Following the nanolayer stack 103 patterning process, one or more nanolayer stacks 103 are formed. As depicted, within each nanolayer stack 103 there is alternating sacrificial nanolayers 106 and active nanolayers 108 formed from the associated blanket nanolayers, respectively. Subsequently, the mask layer may be removed.

The removal of undesired portion(s) of the alternating nanolayers may further remove undesired portions of substrate structure 102 that are adjacent to respective footprints of nanolayer stacks 103 to form STI region openings. The etch may be timed or otherwise controlled to stop the removal of the substrate structure 102 such that the depth or bottom of the one or more STI region openings has a predetermined or desired dimension. Alternatively, the etch may utilize the etch stop layer (not shown) that is internal to the substrate structure 102 to effectively stop the etch to form the depth or bottom of the one or more STI region openings.

A STI region (not shown) may be formed upon the substrate structure 102 below and adjacent to the nanolayer stacks 103 within the STI region openings. For example, one or more STI regions may be formed by depositing isolation material within the STI region openings adjacent to the one or more nanolayer stacks 103. A top surface of the one or more STI regions may be coplanar with a top surface of substrate structure 102. The STI region(s) may be formed by depositing STI isolation material upon the substrate structure 102 to a thickness such that the top surface of the STI isolation material is coplanar with the top surface of the substrate structure 102. The one or more STI regions may have a volume that sufficiently electrically isolates components or features of neighboring transistors, or the like, and/or may sufficiently electrically isolate neighboring nanolayer stacks 103.

Further, in the depicted fabrication stage, one or more sacrificial gate structures 121 are formed upon the substrate structure 102 (not shown in the depicted cross-section), upon STI regions (not shown in the depicted cross-section), and upon and around the one or more nanolayer stacks 103. The one or more sacrificial gate structures 121 may include a sacrificial gate liner (not shown), a sacrificial gate 116, and a sacrificial gate cap 118.

The sacrificial gate structures 121 may be formed by initially depositing the sacrificial gate liner layer (e.g., a dielectric, oxide, or the like) upon the one or more STI regions and upon and around the one or more nanolayer stacks 103. The sacrificial gate structures 121 may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the one or more nanolayer stacks 103. The sacrificial gate structures 121 may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures 121 may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner (not shown), the sacrificial gate 116, and the sacrificial gate cap 118, respectively, of each of the one or more sacrificial gate structures 121.

One or more sacrificial gate structures 121 can be formed on targeted regions or areas of semiconductor IC device 100 to define the length of one or more GAA FETs, length of one or more channels between a respective source and drain, and to provide sacrificial material for yielding targeted GAA FET structure(s) in subsequent processing. According to an example, each sacrificial gate structure 121 can have a height of between approximately 50 nm and approximately 200 nm, and a length of between approximately 10 nm and approximately 200 nm.

One or more gate spacers 120 may be respectively formed upon the substrate structure 102, upon the one or more STI regions, upon and around the one or more nanolayer stacks 103, and upon and around each of the one or more sacrificial gate structures 121. In one example, gate spacers 120 may be formed of a dielectric material(s), such as such as silicon nitride, SiBCN, SiNC, SiN, SiCO, SiNOC, a combination thereof, or the like.

The one or more gate spacers 120 may be formed by a deposition of a blanket gate spacer dielectric material. Excess, undesired, and/or exposed blanket gate spacer dielectric material may be subsequently removed by a substrative removal technique, such as an etch. For example, a directional etch may remove exposed horizontal portion(s) of the blanket gate spacer dielectric material while also leaving vertical portion(s) of the blanket gate spacer dielectric material, upon the sidewall perimeter of each of the one or more sacrificial gate structures 121, intact.

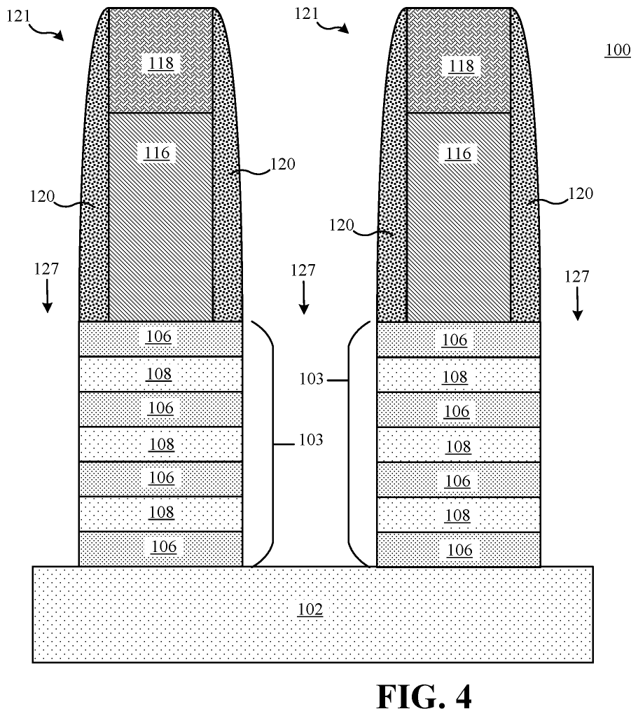

FIG. 4 depicts a cross-sectional view of the semiconductor IC device 100 after fabrication operations, in accordance with embodiments of the present disclosure. In the depicted fabrication stages, source/drain (S/D) recesses 127 are formed within the one or more nanolayer stacks 103 between gate spacers 120 that are associated with neighboring sacrificial gate structures 121. In other words, a single nanolayer stack 103 may be separated into multiple nanolayer stacks 103, each located underneath a sacrificial gate structures 121, by the formation of one or more S/D recesses 127.

The one or more S/D recesses 127 may be formed between adjacent sacrificial gate structures 121 by removing respective portions of the sacrificial nanolayers 106 and active nanolayers 108 that are between gate spacers 120 of adjacent or neighboring sacrificial gate structures 121. The one or more S/D recesses 127 may be formed to a depth to stop at the substrate structure 102. In this manner, a respective nanolayer stack 103 is separated. In the separation, respective portions of the sacrificial nanolayers 106 and the active nanolayers 108 that are located below the gate spacers 120 and below the sacrificial gate structures 121 may be retained. The undesired portions of the nanolayers may be removed by etching or other subtractive removal techniques. The top surface of the substrate structure 102 may be used as an etch stop or other etch parameters may be controlled to stop the material removal at the substrate structure 102. The retained one or more portions of one or more nanolayer stacks 103 may be such portions of the alternating nanolayers that were protected generally below and/or internal to respective sacrificial gate structures 121 and/or by the associated gate spacers 120. As such, as is depicted, respective sidewalls or end surfaces of the retained sacrificial nanolayers 106 and the active nanolayers 108 may be coplanar with respective outer sidewalls of the associated gate spacers 120.

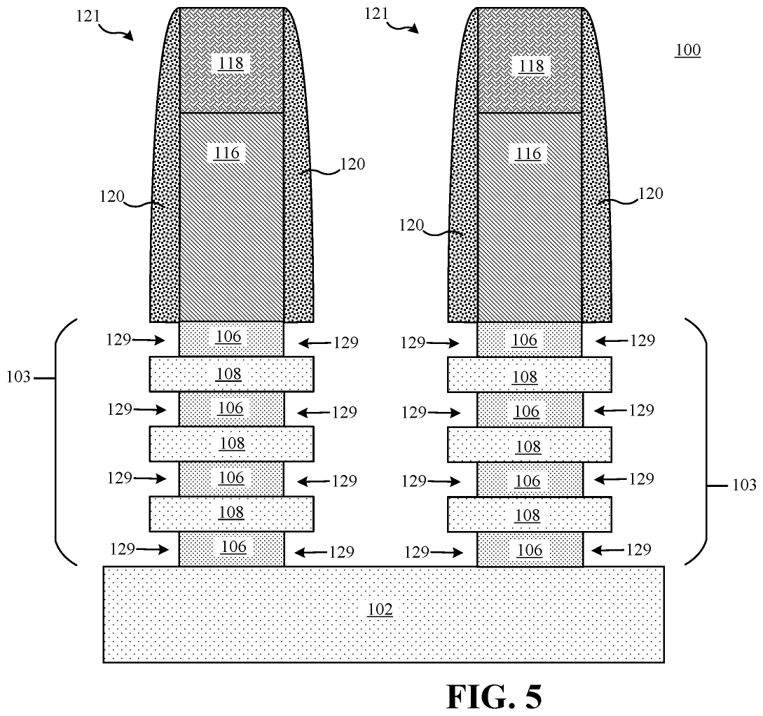

FIG. 5 depicts a cross-sectional view of the semiconductor IC device 100 after fabrication operations, in accordance with embodiments of the present disclosure. In the depicted fabrication stages, indents 129 are formed by removing respective portions of sacrificial nanolayers 106 that are not covered by the sacrificial gate 116.

Indents 129 may be formed by a reactive ion etch (RIE) process and a wet etch process, which can remove portions of the sacrificial nanolayers 106 not covered by the sacrificial gate 116 (and the sacrificial gate cap 118). The horizontal depth of the indents 129 may be chosen to set a length for the replacement gate structure formed in place of the sacrificial gate structure 121. When the sacrificial nanolayers 106 are composed of SiGe, the directional RIE can use a boron-based chemistry or a chlorine-based chemistry, for example, which recesses or removes the exposed end portions of sacrificial nanolayers 106 (e.g., those portions of sacrificial nanolayers 106 generally below spacer 120, etc.) selective to the Si active nanolayers 108. In alternative implementations when sacrificial nanolayers 106 are not SiGe and when active nanolayers 108 are not Si, the directional etch of the sacrificial nanolayers 106 may generally be selective to the active nanolayers 108, gate spacers 120, and/or substrate structure 102.

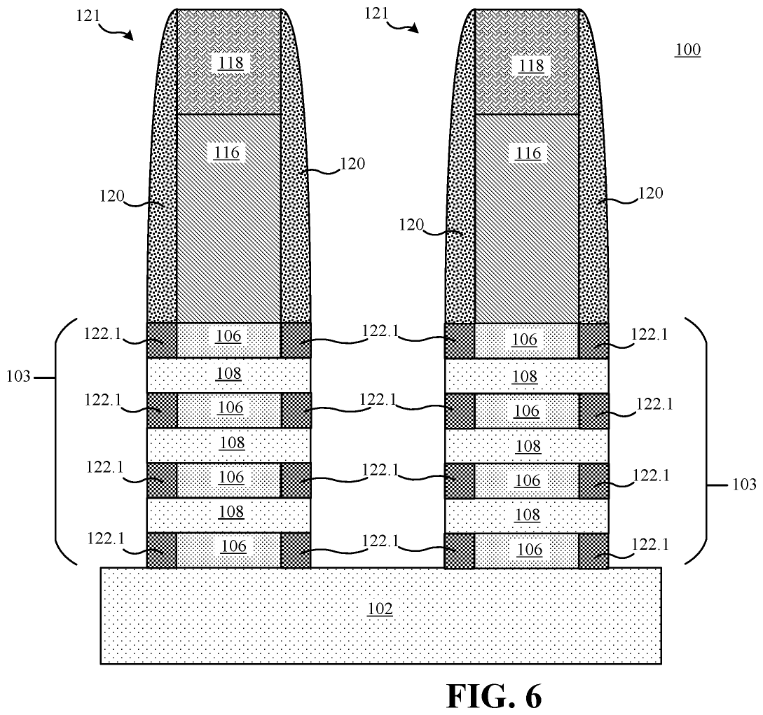

FIG. 6 depicts a cross-sectional view of the semiconductor IC device 100 after fabrication operations, in accordance with embodiments of the present disclosure. In the depicted fabrication stages, a respective inner spacer 122.1 is formed within the one or more indents 129.

The one or more inner spacers 122.1 can be formed by ALD or CVD or any other suitable deposition technique that deposits material within the indents 129, thereby forming inner spacers 122.1. In some examples, the inner spacers 122.1 are composed of a low-K dielectric material (a material with a lower dielectric constant relative to SiO₂), SiN, SiO, SiBCN, SiOCN, SiCO, etc. or any other suitable dielectric material. In certain implementations, after the formation of the inner spacers 122.1, an isotropic etch process is performed to create outer vertical surfaces of the inner spacers 122.1 that align with outer vertical surfaces of the active nanolayers 108 and/or of the gate spacers 120.

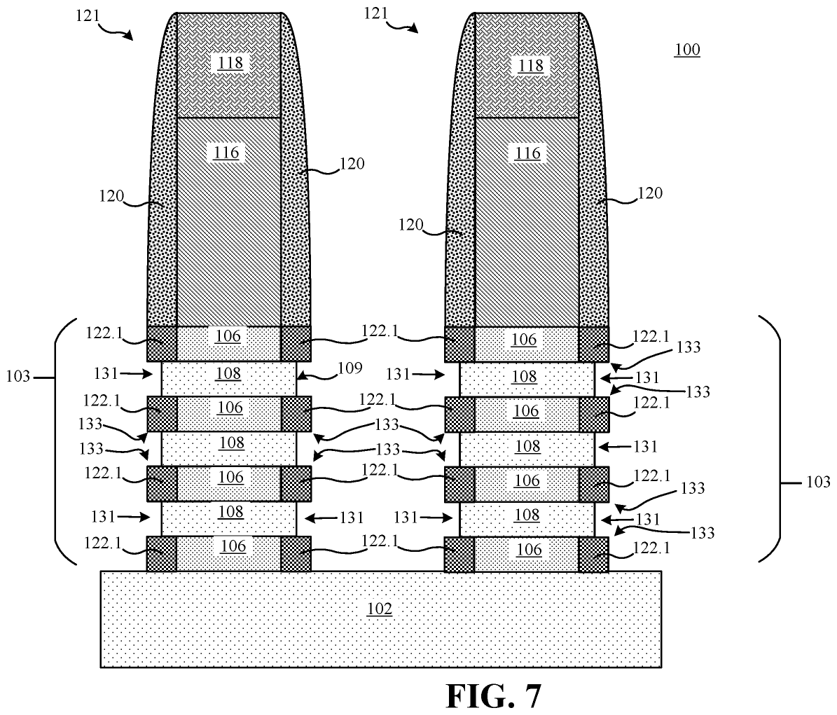

FIG. 7 depicts a cross-sectional view of the semiconductor IC device 100 after fabrication operations, in accordance with embodiments of the present disclosure. In the depicted fabrication stages, indents 131 are formed by at least partially removing respective portions of active nanolayers 108 that are underneath a respective gate spacer 120 to form exposed external corner region 133 of inner spacer(s) 122.1 there above and/or there below.

Indents 131 may be formed by an etch process, which can remove portions of the active nanolayers 108 that are underneath the gate spacer 120. The horizontal depth of the indents 131 may be controlled to result in the inset surface or well of the etch being inset within the inner spacer(s) 122.1 there above and/or there below. For example, as depicted, after formation of an associated indent 131 an end surface 109 of the active nanolayer 108 is between a left sidewall or surface and right sidewall or surface of the inner spacer(s) 122.1 there above and/or there below. Such positioning may be important to ensure that S/D region material does not directly contact the to be formed replacement gate and to form the exposed external corner region 133. In an implementation the indents 131 may form a concave end surface 109 of the active nanolayer 108 which may advantageously increase the volume of the funneled interfacial region of the S/D region 134.

The etch of the active nanolayers 108 to form indents 131 may generally be selective to the respective materials of inner spacers 122.1, gate spacers 120, or the like. The etch of the active nanolayers 108 to form indents 131 may be directional and remove exposed vertical portion(s) of the active nanolayers 108.

Formation of indents 131 result in an exposed external corner region 133 of the inner spacers 121.2. In an example, the exposed external corner region 133 is a corner of the inner spacer 122.1 where a substantially vertical sidewall of the inner spacer 122.1 meets a substantially horizontal top surface or bottom surface of the inner spacer 122.1, respectively. Though depicted as ninety-degree edge with a width into and out of the page parallel to the associated gate width, the exposed external corner region 133 need not have an orthogonal corner. For example, the exposed external corner region 133 may have one or more nonlinear surfaces that form the corner or transition between the substantially vertical sidewall of the inner spacer 122.1 and the substantially horizontal top surface and/or bottom surface of the inner spacer 122.1.

For clarity, in an example as depicted, a first inner spacer 122.1 is between substrate structure 102 and an active nanolayer 108 there above. The bottom surface of the first inner spacer 122.1 is therefore protected by the substrate structure 102 and the top surface of the first inner spacer 122.1 is partially exposed by the indent 131. A second inner spacer 122.1 is between gate spacer 120 there above and an active nanolayer 108 there below. The top surface of the second inner spacer 122.1 is therefore protected by the gate spacer 120 and the bottom surface of the second inner spacer 122.1 is partially exposed by the indent 131. A third inner spacer 122.1 is located between an active nanolayer 108 there above and an active nanolayer 108 there below. The top surface and bottom surface of the third inner spacer 122.1 are respectively partially exposed by associated indents 131.

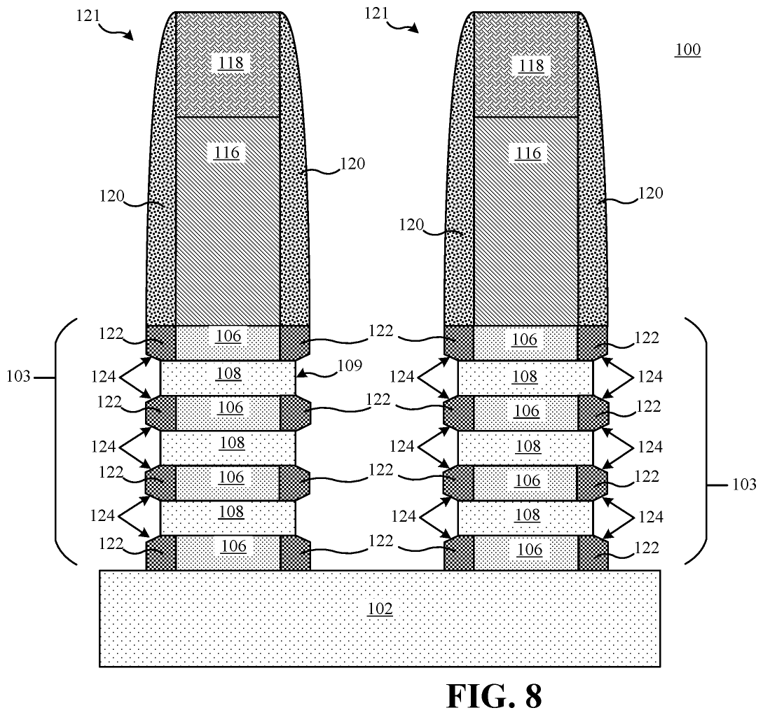

FIG. 8 depicts a cross-sectional view of the semiconductor IC device 100 after fabrication operations, in accordance with embodiments of the present disclosure. In the depicted fabrication stages, exposed external corner region(s) 133 of inner spacer(s) 122.1 are recessed and thereby form funneled inner spacer(s) 122 that include at least one or more receded non-orthogonal corners 124.

The receded non-orthogonal corner 124 generally has a receded or recessed edge or corner between a top and/or bottom surface (e.g., which may be substantially horizontal, or the like) and side surface (e.g., which may be substantially vertical, or the like) of the inner spacer. The funneled inner spacer(s) 122 may be formed by a subtractive removal technique, such as an etch, that at least partially removes the corners between the top and/or bottom surface (e.g., which may be substantially horizontal, or the like) and the side surface (e.g., which may be substantially vertical, or the like) of the inner spacer.

In an example, the subtractive removal technique directionally removes the exposed corner(s) of the inner spacer 122.1 to form a linear and angled surface (e.g., a chamfered surface) between the top and/or bottom surface and the side surface of the funneled inner spacer 122. In another example, the subtractive removal technique removes the exposed corner(s) of the inner spacer 122.1 to form a rounded surface (e.g., a filleted surface) between the top and/or bottom surface and the side surface of the funneling inner spacer 122. The chamfered surface and/or the filleted surface may be generally located outward or external from the end surface 109 of the associated active nanolayer 108.

In another example, the subtractive removal technique directionally removes the exposed corner(s) and one or more portions of the top and/or bottom surface and the side surface of the inner spacer 122.1 to form a nonlinear surface of the funneling inner spacer 122 that generally is located outward or external from the end surface 109 of the associated active nanolayer 108.

The etch may be a dry or wet etch. In such process(es), the dry and wet etching processes can have etching parameters that can be tuned, such as etchants used, etching temperature, etching solution concentration, etching pressure, source power, RF bias voltage, RF bias power, etchant flow rate, and other suitable parameters and selective materials are utilized to promote the etchant for desired material removal.

The etch may be an ion based etch, such as an RIE. In such process(es), the ion etching processes can have etching parameters that can be tuned, such as ion angle, concentration, or the like, to promote the ion etch to achieve desired material removal.

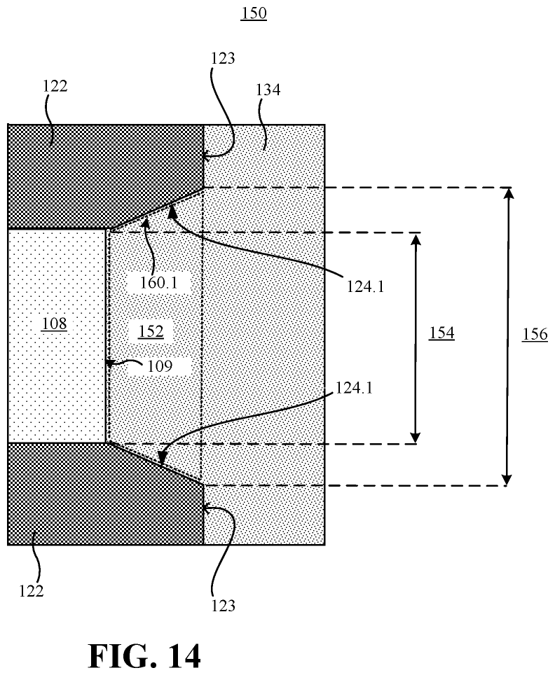

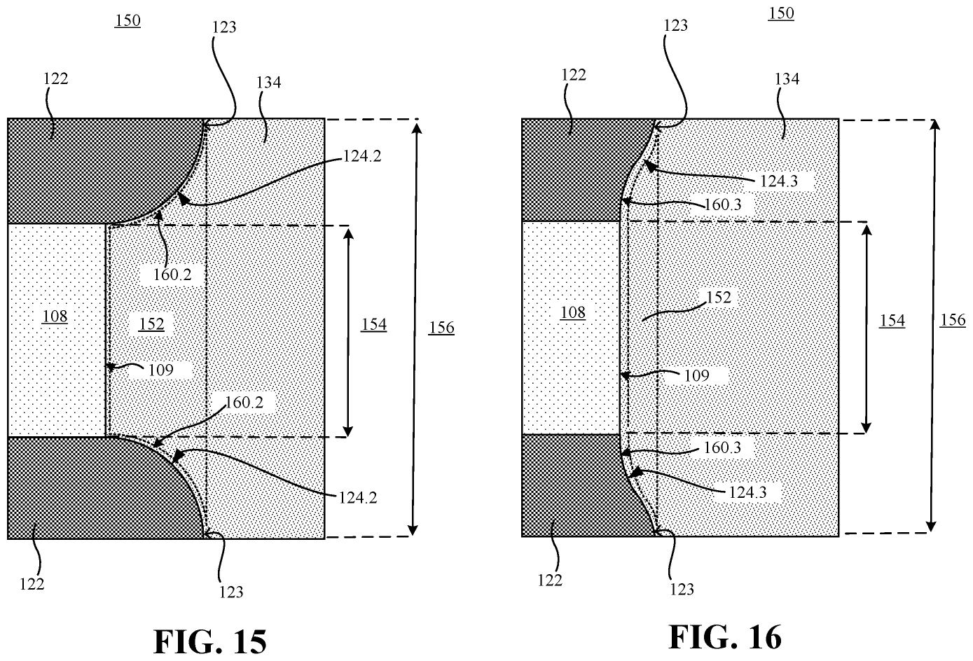

As depicted in FIG. 14, funneled inner spacer(s) 122 may include receded chamfered non-orthogonal corners 124.1. As depicted in FIG. 15, funneled inner spacer(s) 122 may include receded filleted non-orthogonal corners 124.2. As depicted in FIG. 16, funneled inner spacer(s) 122 may include receded non-linear non-orthogonal corners 124.3. Though a chamfered, filleted, and non-linear shape of funneled inner spacer(s) 122 is illustratively depicted, many other shapes are contemplated that resultantly form the funneled interfacial region of the S/D region 134 in which the narrow throat is juxtaposed directed against the end surface 109 of associated active nanolayer 108.

For clarity, in an example as depicted, a first funneling inner spacer 122 is between substrate structure 102 and active nanolayer 108 there above. The bottom surface of the first funneling inner spacer 122 was protected by the substrate structure 102 and the corner associated therewith is substantially not exposed to or minimally exposed to the substrative removal technique that otherwise forms the receded non-orthogonal corners 124. As such the first funneling inner spacer 122 has a substantially orthogonal bottom corner and a receded non-orthogonal top corner 124.

Similarly, a second funneling inner spacer 122 is between gate spacer 120 directly there above and active nanolayer 108 directly there below. The top surface of the second funneling inner spacer 122 was protected by the gate spacer 120, and the corner associated therewith is substantially not exposed to or minimally exposed to the substrative removal technique that otherwise forms the receded non-orthogonal corners 124. As such the second funneling inner spacer 122 has a substantially orthogonal top corner and a receded non-orthogonal bottom corner 124.

Likewise, a third funneling inner spacer 122 is between an active nanolayer 108 directly there above and another active nanolayer 108 directly there below. Both the top surface and bottom surface of the third funneling inner spacer 122 have associated corners that were exposed by the indents 131 associated with these active nanolayers 108 and therefore subject to the substrative removal technique that forms the receded non-orthogonal corners 124. As such the third funneling inner spacer 122 has a substantially both a receded non-orthogonal top and bottom corner 124.

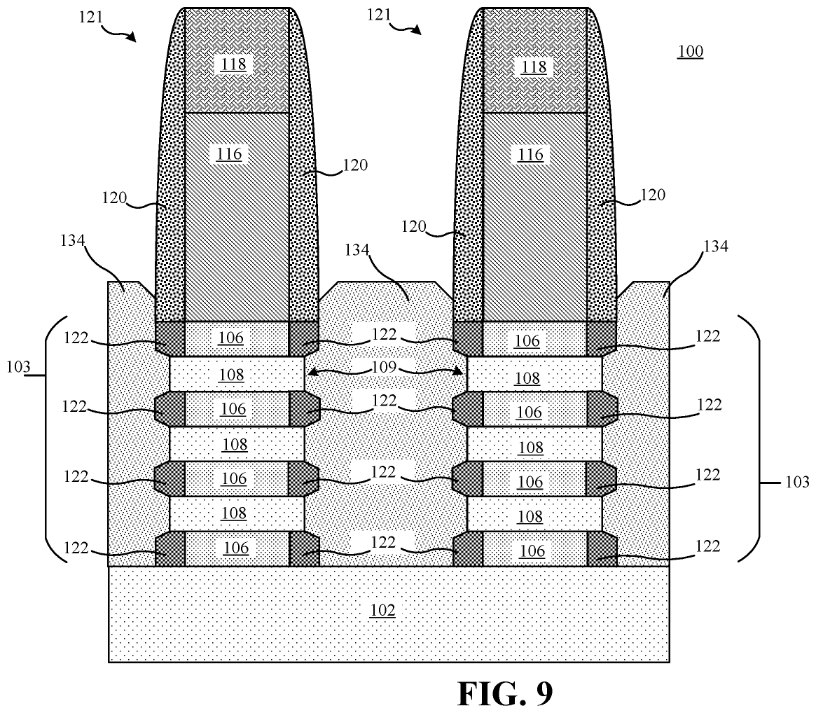

FIG. 9 depicts a cross-sectional view of the semiconductor IC device 100 after fabrication operations, in accordance with embodiments of the present disclosure. In the depicted fabrication stages, one or more source/drain (S/D) regions 134 are formed over respective sidewalls of neighboring nanolayer stacks 103.

Each S/D region 134 forms either a source or a drain, respectively, of respective one or more GAA FETs and is connected to respective end surfaces 109 of active nanolayers 108 thereof. Each of the S/D region 134 is composed of a semiconductor material and a dopant. As used herein, a “source/drain” region can be a source region or a drain region depending on subsequent wiring and application of voltages during operation of the transistor. The semiconductor material that provides each of the S/D region 134 is composed of one of the semiconductor materials mentioned above for the semiconductor structure 102. The semiconductor material that provides the S/D region 134 can be compositionally the same, or compositionally different from each active nanolayers 108. The semiconductor material that provides each active nanolayers 108 is however compositionally different from each sacrificial nanolayer 106. The dopant that is present in the S/D region 134 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each of the S/D region 134 can have a dopant concentration of from 1×10²⁰ atoms/cm³ to 3×10²¹ atoms/cm³.

S/D region(s) 134 may be epitaxially grown or formed. The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

The S/D region(s) 134 may be formed by epitaxially growing a source/drain epitaxial region within the recess or opening between neighboring nanolayer FETs. In some examples, S/D region(s) 134 are formed by in-situ doped epitaxial growth. In some embodiments, the S/D region(s) 134 epitaxial growth may overgrow above the upper surface of the semiconductor IC device 100.

Suitable n-type dopants include but are not limited to phosphorous (P), and suitable p-type dopants include but are not limited to boron (B). The use of an in-situ doping process is merely an example. For instance, one may instead employ an ex-situ process to introduce dopants into the source and drains. Other doping techniques can be used to incorporate dopants in the bottom source/drain region. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In preferred embodiments, the S/D epitaxial growth conditions that promote in-situ Boron doped SiGe for p-type transistor and phosphorus or arsenic doped silicon or Si:C for n-type transistors.

In certain implementations, the S/D region(s) 134 may be overgrown and then partially recessed such that an upper portion of the S/D region(s) 134 are removed. For example, the upper portion of the one or more S/D region(s) 134 may be etched or otherwise removed. The etch may be timed or otherwise controlled to stop the removal of S/D region(s) 134 such that the top surface of S/D region(s) 134 is above the upper surface of the topmost active nanolayer 108 so as to appropriately contact the end surface 109 of the topmost active nanolayer 108 channel and such that the top surface of the S/D region(s) 134 is below the upper surface of sacrificial gate structure 121 to maintain the ability to expose and remove the sacrificial gate structure 121.

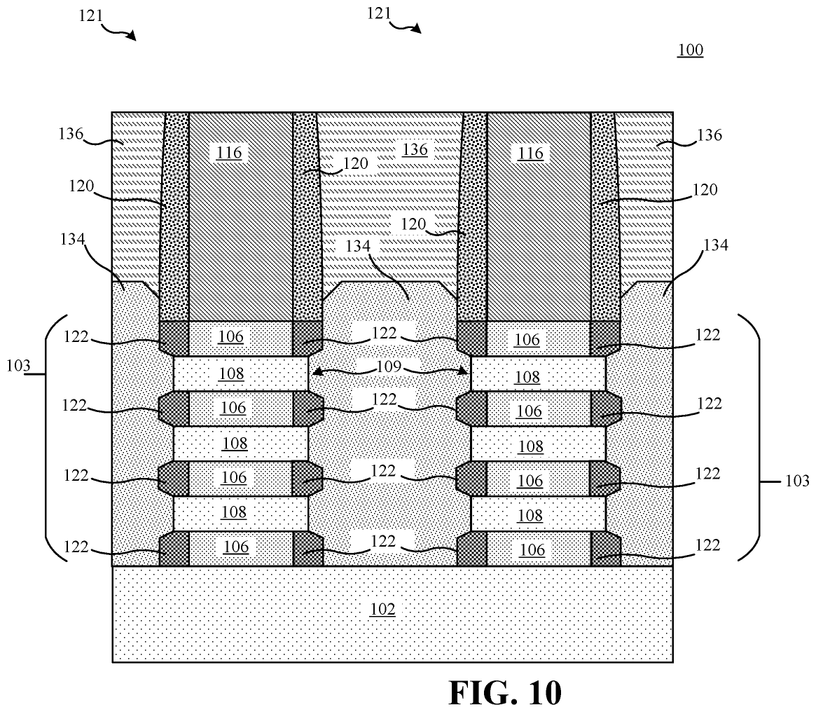

FIG. 10 depicts a cross-sectional view of the semiconductor IC device 100 after fabrication operations, in accordance with embodiments of the present disclosure. In the depicted fabrication stages, interlayer dielectric (ILD) 136 is formed upon the one or more source/drain (S/D) regions 134 and upon at least the sidewalls of the sacrificial gate structures 121 and may be further formed upon the STI region(s) (if present) and/or the substrate structure 102.

The ILD 136 may be formed by depositing a dielectric material upon S/D region(s) 134 and upon at least the sidewalls of the sacrificial gate structures 121 and may be further formed upon the STI region(s) (if present) and/or the substrate structure 102. The ILD 136 can be any suitable material, such as, for example, porous silicates, carbon doped oxides, silicon dioxides, silicon nitrides, silicon oxynitrides, or other dielectric materials. Any known manner of forming the ILD 136 can be utilized. The ILD 136 can be formed using, for example, CVD, PECVD, ALD, flowable CVD, spin-on dielectrics, or PVD.

In an example, the ILD 136 may be formed to a thickness above the top surface of the sacrificial gate structures 121. Subsequently, a planarization process, such as a CMP, may be performed to remove the sacrificial gate cap 118, to partially remove the excess ILD 136, and to partially remove the gate spacers 120. The planarization may also partially remove some of the sacrificial gate 116 or may at least expose the sacrificial gate 116 of the sacrificial gate structures 121. The CMP may create a planar or horizontal top surface for the semiconductor IC device 100. In other words, the respective top surfaces of ILD 136, gate spacers 120, sacrificial gates 116 may be coplanar.

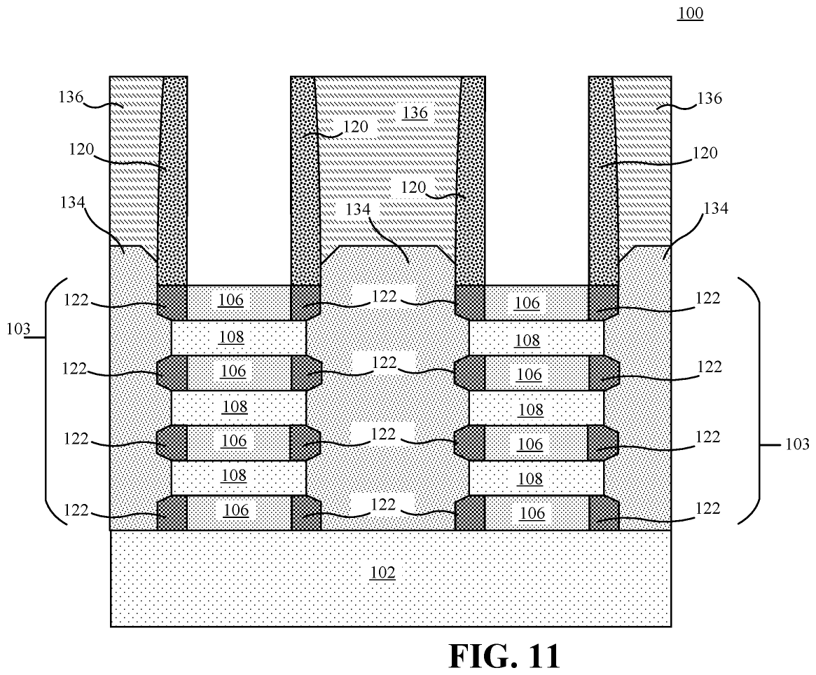

FIG. 11 depicts a cross-sectional view of the semiconductor IC device 100 after fabrication operations, in accordance with embodiments of the present disclosure. In the depicted fabrication stages, the sacrificial gate structures 121 are removed.

The sacrificial gate structure 121 may be removed by initially removing the sacrificial gate 116 and sacrificial gate oxide by a removal technique, such as one or more series of etches. For example, such removal may be accomplished by an etching process which may include a dry etching process such as RIE, plasma etching, ion etching or laser ablation. The etching can further include a wet chemical etching process in which one or more chemical etchants are used to remove the sacrificial gate 116 and sacrificial gate oxide of the sacrificial gate structures 121. Appropriate etchants may be used that remove the sacrificial gate 116 and/or sacrificial gate oxide selective to the active nanolayers 108, funneling inner spacers 122, gate spacers 120, or the like.

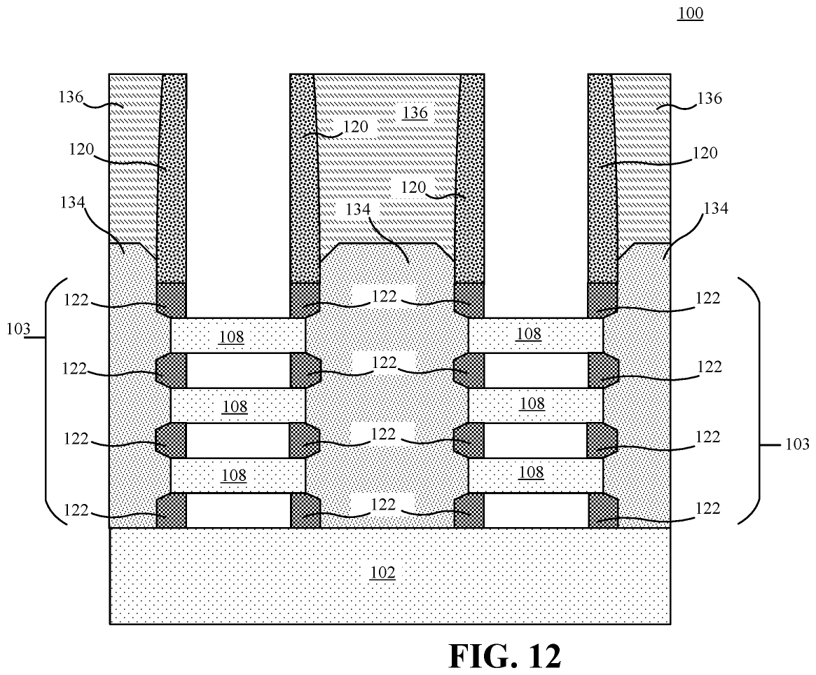

FIG. 12 depicts a cross-sectional view of the semiconductor IC device 100 after fabrication operations, in accordance with embodiments of the present disclosure. In the depicted fabrication stages, the active nanolayers 108 are released by removing the sacrificial nanolayers 106.

The sacrificial nanolayers 106 may be removed by a removal technique, such as one or more series of etches. For example, the etching can include a wet chemical etching process in which one or more chemical etchants are used to remove the sacrificial nanolayers 106. Appropriate etchants may be used that remove the sacrificial nanolayers 106 selective to the active nanolayers 108, funneling inner spacers 122, gate spacers 120, or the like. After the removal of sacrificial nanolayers 106, there are void spaces between the active nanolayers 108.

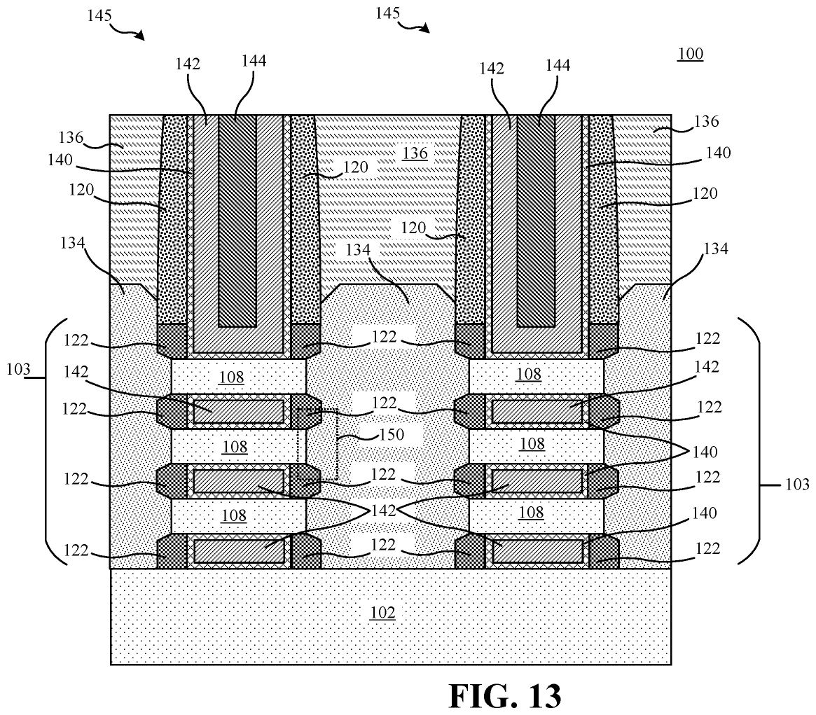

FIG. 13 depicts a cross-sectional view of the semiconductor IC device 100 after fabrication operations, in accordance with embodiments of the present disclosure. In the depicted fabrication stages, replacement gate structures 145 are formed around the active nanolayers 108 in place of the removed sacrificial gate structures 121. FIG. 13 also depicts a region 150 that is enlarged in subsequent figures.

Replacement gate structure(s) 145 may be formed by initially forming an interfacial layer (not shown) on the interior surfaces of the gate spacer 120 and the interior surfaces of the active nanolayers 108, the funneling inner spacers 122, etc. Then, a high-K layer 140 is formed to cover the surfaces of exposed surfaces of the interfacial layer. The high-K layer 140 can be deposited by any suitable techniques, such as ALD, CVD, metal-organic CVD (MOCVD), physical vapor deposition (PVD), thermal oxidation, combinations thereof, or other suitable techniques. A high-K dielectric material is a material with a higher dielectric constant than that of SiO₂, and can include e.g., LaO, AlO, ZrO, TiO, Ta₂Os, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr) TiO₃ (BST), Al₂O₃, Si₃N₄, oxynitrides (SiON), or other suitable materials. The high-K layer 140 can include a single layer or multiple layers, such as metal layer, liner layer, wetting layer, and adhesion layer.

Replacement gate structure(s) 145 may be further formed by depositing a work function metal (WFM) gate 142 upon the high-K layer 140. The WFM gate 142 can be comprised of metals, such as, e.g., copper (Cu), cobalt (Co), aluminum (Al), platinum (Pt), gold (Au), tungsten (W), titanium (Ti), nitride (N) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In various exemplary embodiments, the height of the WFM gate 142 can be reduced by chemical-mechanical polishing (CMP) and/or etching. Therefore, the planarization process can be provided by CMP. Other planarization process can include grinding and polishing. In general, the work function metal (WFM) gate 142 sets the threshold voltage (Vt) of the device. The high-K layer 140 separates the WFM gate 142 from the nanolayer channel (i.e., active nanolayers 108). Other metals that may be desired to further fine tune the effective work function (eWF) and/or to achieve a desired resistance value associated with current flow through the gate in the direction parallel to the plane of the nanolayer channel.

The one or more replacement gate structures 145 may be further formed by depositing a conductive fill gate 144 upon the WFM gate 142. The conductive fill gate 144 can be comprised of metals, such as but not limited to, e.g., tungsten, aluminum, ruthenium, rhodium, cobalt, copper, tantalum, titanium, carbon nanowire materials including graphene, or the like. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. After the replacement gate structure 145 formation, the top surface of the semiconductor IC device 100 may be planarized by a planarization technique such as a CMP, mechanical grinding process, or the like. After the planarization technique, respective top surfaces of the ILD 136, gate spacers 120, replacement gate structure(s) 145, may be horizontal and/or may be coplanar.

In examples, semiconductor IC device 100 may be subjected to further fabrication stages, such as formation of an second ILD upon the ILD 136 and upon the replacement gate structure(s) 145, formation of one or more middle of the line (MOL) contacts, such a source MOL contact that melds with a source S/D region 134, a drain MOL contact that melds with a drain S/D region 134, a gate MOL contact that melds with a replacement gate structure. Semiconductor IC device 100 may be subjected to further fabrication stages, such as formation of a back end of the line (BEOL) network upon the second ILD and upon the MOL contacts. The BEOL network may include metallization levels with signal line and/or power rails, associated metallization dielectric layers, VIAs that connect the signal traces and/or power rails within the metallization levels with an underlying device or structure, and/or conductive bonding pads, or the like.

FIG. 14 depicts illustrative funneling inner spacers 122 (e.g., a top funneling spacer 122 above the active nanolayer 108 and a bottom funneling spacer 122 below the active nanolayer 108) with a chamfered receded non-orthogonal corner 124.1, respectively, according to one or more embodiments of the disclosure. The chamfered receded non-orthogonal corner 124.1 is a substantially linear sloping surface at an edge or corner of the funneling inner spacer 122 that is receded or recessed from an orthogonal corner of the top or bottom surface (e.g., which may be substantially horizontal, or the like) and side surface (e.g., which may be substantially vertical, or the like) of that inner spacer 122.

The funneled interfacial region 152 is horizontally between the active nanolayer 108 and the remainder of the S/D region 134 and resultingly and advantageously may decreases a parasitic resistance between the S/D region 134 and the active nanolayer 108. The wide throat of the funneled interfacial region 152 may be an integral interface between the remainder of the S/D region 134 and the funneled interfacial region 152. For clarity, the funneled interfacial region 152 is integral to the S/D region 134. In other words, no junctions exist between the funneled interfacial region 152 and the S/D region 134. As such, there is substantially no interfacial electrical impedance between the funneled interfacial region 152 is integral to the S/D region 134. The funneled interfacial region 152 may be referred to as a junction thickness of the S/D region 134 associated with a particular active nanolayer 108. Because thickness 156 is greater than thickness 154, and because thickness 154 is associated with or substantially the same as the thickness of the active nanolayer 108, this junction thickness formed by the funneled interfacial region 152 is greater than the thickness of the associated active nanolayer 108.

The funneled interfacial region 152 is defined by the wide throat which is a planar cross-sectional area (e.g., into and out of the page) associated with thickness 156 that is coplanar with an outer side surface or outermost point 123 of the funneling inner spacer 122 there above or there below. On a side opposite or distal side relative to wide throat, the funneled interfacial region 152 is defined by the narrow throat which is a planar cross-sectional area (e.g., into and out of the page) associated with thickness 154 and/or the end surface 109 of the associated active nanolayer 108.

The chamfered receded non-orthogonal corner 124.1 may effectively form a substantially chamfered linear surface 160.1 of the funneled interfacial region 152. The chamfered linear surface 160.1 connects the narrow throat to the wide throat, as depicted. The chamfered linear surface 160.1 may extend from an intersection of the top surface and end surface 109 of the associated active nanolayer 108. Further, chamfered linear surface 160.1 may extend from an intersection of the bottom surface and end surface 109 of the associated active nanolayer 108. In an alternative example, the chamfered linear surface 160.1 may have an origin that is coplanar with the top surface or bottom surface of the associated active nanolayer 108. The chamfered linear surface 160.1 is generally and substantially juxtaposed directly against the chamfered receded non-orthogonal corner 124.1, as depicted.

FIG. 15 depicts illustrative funneling inner spacers 122 e.g., a top funneling spacer 122 above the active nanolayer 108 and a bottom funneling spacer 122 below the active nanolayer 108) with a filleted receded non-orthogonal corner 124.2, respectively, according to one or more embodiments of the disclosure. The filleted receded non-orthogonal corner 124.2 is a substantially rounded or arced surface at an external edge or corner of the funneling inner spacer 122 that is receded or recessed from an orthogonal corner of the top or bottom surface (e.g., which may be substantially horizontal, or the like) and side surface (e.g., which may be substantially vertical, or the like) of that inner spacer 122.

The funneled interfacial region 152 is defined by the wide throat associated with thickness 156. On a side opposite or distal side relative to wide throat, the funneled interfacial region 152 is defined by the narrow throat. The filleted receded non-orthogonal corner(s) 124.2 may effectively form a substantially filleted surface 160.2 of the funneled interfacial region 152. The filleted surface 160.2 connects the narrow throat to the wide throat, as depicted. The filleted surface 160.2 may extend from an intersection of the top surface and end surface 109 of the associated active nanolayer 108. Further, filleted surface 160.2 may extend from an intersection of the bottom surface and end surface 109 of the associated active nanolayer 108. In an alternative example, the filleted surface 160.2 may have an origin that is coplanar with the top surface or bottom surface of the associated active nanolayer 108. The filleted surface 160.2 is generally and substantially juxtaposed directly against the filleted receded non-orthogonal corner(s) 124.2, as depicted.

FIG. 16 depicts illustrative funneling inner spacers 122 (e.g., a top funneling spacer 122 above the active nanolayer 108 and a bottom funneling spacer 122 below the active nanolayer 108) with a non-linear receded non-orthogonal corner 124.3, respectively, according to one or more embodiments of the disclosure. The non-linear receded non-orthogonal corner 124.3 multiple non-linear or arced surfaces at an external edge or corner of the funneling inner spacer 122 that is receded or recessed from an orthogonal corner of the top or bottom surface (e.g., which may be substantially horizontal, or the like) and side surface (e.g., which may be substantially vertical, or the like) of that inner spacer 122.

The funneled interfacial region 152 is defined by the wide throat associated with thickness 156. On a side opposite or distal side relative to wide throat, the funneled interfacial region 152 is defined by the narrow throat. The non-linear receded non-orthogonal corner 124.3 may effectively form a substantially non-linear surface 160.3 of the funneled interfacial region 152. The non-linear surface 160.3 connects the narrow throat to the wide throat, as depicted. The non-linear surface 160.3 may extend from an intersection of the top surface and end surface 109 of the associated active nanolayer 108. Further, the non-linear surface 160.3 may extend from an intersection of the bottom surface and end surface 109 of the associated active nanolayer 108. In an alternative example, the non-linear surface 160.3 may have an origin that is coplanar with the top surface or bottom surface of the associated active nanolayer 108. The non-linear surface 160.3 is generally and substantially juxtaposed directly against the non-linear receded non-orthogonal corner 124.3, as depicted.

For clarity, in one implementation a volume of the funneled interfacial region 152 may be maximized, which may resultantly and advantageously minimize the parasitic resistance between the S/D region 134 and the active nanolayer 108. Further, the thickness 154 may be the thickness (i.e., dimension between the top surface and bottom surface) of the associated active nanolayer 108.

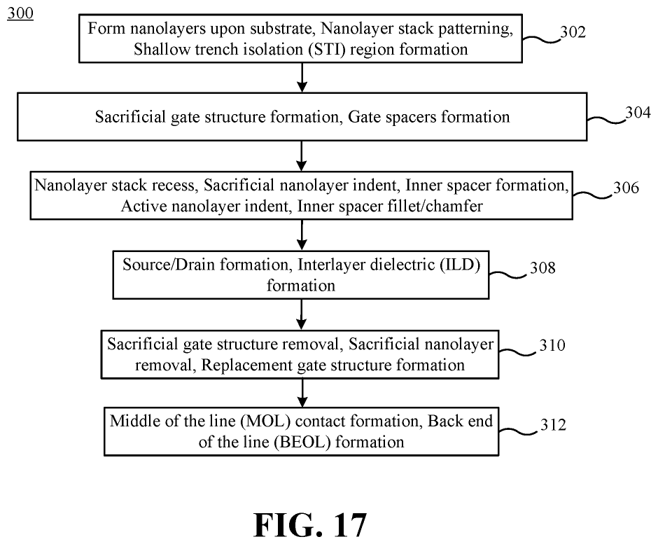

FIG. 17 depicts a flow diagram illustrating method 300 to fabricate a semiconductor IC device, such as semiconductor IC device 100. The depicted fabrication operations of method 300 are illustrated and described above with reference to one or more of FIG. 2 through FIG. 13 of the drawings, which describe the fabrication of semiconductor IC device 100, though the fabrication operations described in method 300 may be used to fabricate other types of semiconductor IC devices. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with forming nanolayers upon a substrate and patterning the nanolayers into one or more nanolayer stacks. For example, method 300 may include forming alternating series of sacrificial nanolayers 106 and active nanolayers 108 upon a substrate structure 102. Further, method 300 may include pattering the nanolayers to form one or more nanolayer stack(s) 103 and forming STI regions therebetween. For example, predetermined portions of the nanolayers may be removed and a well within the substrate structure 102 may be formed. The portions of the nanolayers that remain may effectively form the one or more nanolayer stacks 103 and respective STI regions may be formed within the substrate well between the nanolayer stacks 103.

At block 304, method 300 may further continue with forming one or more sacrificial gate structure(s) and with forming one or more gate spacers upon the one or more sacrificial gate structure(s). For example, method 300 may include forming one or more sacrificial gate structures 121 upon the substrate structure 102, upon the STI regions, and upon and around the nanolayer stack(s) 103. Further, method 300 may include forming one or more gate spacer(s) 121 upon the substrate structure 102 and/or upon the STI regions and upon the sidewall(s) of the sacrificial gate structures 121. For example, the gate spacer(s) 120 may be formed upon the substrate structure 102 or upon the STI regions, may be formed upon and around nanolayer stack(s) 103 and may be formed upon and around the one or more sacrificial gate structure(s) 121, respectively.

At block 306, method 300 may further continue with recessing the nanolayer stacks, with indenting the sacrificial nanolayers within the nanolayer stacks, with forming a respective inner spacer within the recesses or indent, with indenting the active nanolayers within the nanolayer stacks, and with partially recessing the inner spacer to form a funneling inner spacer.

For example, method 300 may include forming S/D recesses 127 within the nanolayer stack(s) 103 between gate spacers 120 associated with neighboring sacrificial gate structures 121. Further, method 300 may include indenting the sacrificial nanolayers 106 within nanolayer stack(s) 103, thereby forming an indent 129. Method 300 may further include forming an inner spacer 122.1 within a respective indent 129. Further, method 300 may include indenting the active nanolayers 108 within nanolayer stack(s) 103, thereby forming an indent 131. Method 300 may further include forming the funneling inner spacer 122 by recessing the exposed external corner region 133 of the bottom surface (e.g., which may be substantially horizontal, or the like) and side surface (e.g., which may be substantially vertical, or the like) of the inner spacer 122.1.

At block 308, method 300 may further continue with forming one or more S/D regions and with forming an ILD. For example, method 300 may include forming respective S/D regions 134 upon the substrate structure 102. Still further, method 300 may include forming ILD 135 upon S/D region(s) 134, upon substrate structure 102, upon STI regions, and upon the sidewall(s) of the sacrificial gate structures 121.

At block 310, method 300 may continue with removing the one or more sacrificial gate structure(s), with removing the sacrificial nanolayers, and with forming a replacement gate structure within the void or recess formed by the absence of a respective sacrificial gate structure. For example, method 300 may include removing the sacrificial gate structure(s) 121, with removing the sacrificial nanolayers 106, and with forming a respective replacement gate structure(s) 145 in place of a respective sacrificial gate structure 121.

At block 312, method 300 may continue with MOL contact formation and with frontside back end of line (BEOL) network formation. For example, method 300 may include forming a second ILD upon the replacement gate structure(s) 145 and upon the ILD 135 and with forming a frontside contact upon one or more S/D regions 134 or one or more replacement gate structures 145. Further, method 300 may include forming the frontside BEOL network upon the second ILD and upon the frontside contacts. In some implementations, method 300 may also include subsequent fabrication stages to, for example, fabricate an IC chip, an end product, or the like.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A transistor comprising:
a gate around a channel;
a top funneling inner spacer directly upon a top surface of the channel; and
a source/drain (S/D) region directly upon the top funneling inner spacer, the S/D region comprising a funneled interfacial region that includes a wide throat and a narrow throat that is directly upon an end surface of the channel.

2. The transistor of claim 1, wherein the wide throat is an integral interface between the funneled interfacial region and a remainder of the S/D region.

3. The transistor of claim 1, wherein the top funneling inner spacer comprises a first receded non-orthogonal corner between a bottom surface of the top funneling inner spacer and an outer sidewall of the top funneling inner spacer.

4. The transistor of claim 3, wherein the first receded non-orthogonal corner is chamfered.

5. The transistor of claim 3, wherein the first receded non-orthogonal corner is filleted.

6. The transistor of claim 3, wherein the first receded non-orthogonal corner is non-linear.

7. The transistor of claim 3, wherein the funneled interfacial region further comprises one or more surfaces that connect the narrow throat to the wide throat.

8. The transistor of claim 3, wherein the end surface of the channel is inset between the outer sidewall of the funneling inner spacer and an inner sidewall of the funneling inner spacer.

9. The transistor of claim 1, wherein the end surface of the channel is concave.

10. The transistor of claim 1, further comprising:
a bottom funneling inner spacer directly upon a bottom surface of the channel.

11. The transistor of claim 10, wherein the bottom funneling inner spacer comprises a second receded non-orthogonal corner between a top surface of the bottom funneling inner spacer and an outer sidewall of the bottom funneling inner spacer.

12. The transistor of claim 7, wherein the one or more surfaces that connect the narrow throat to the wide throat are juxtaposed directly upon the receded non-orthogonal corner.

13. A transistor comprising:
a gate around a channel; and
a source/drain (S/D) region directly upon the first funneling inner spacer, the S/D region comprising a funneled interfacial region that includes a wide throat and a narrow throat that is directly upon an end surface of the channel.

14. The transistor of claim 13, wherein the wide throat is an integral interface between the funneled interfacial region and a remainder of the S/D region.

15. The transistor of claim 13, wherein the wide throat has a larger circumference relative to the narrow throat.

16. The transistor of claim 13, wherein a linear surface connects the narrow throat and the wide throat.

17. The transistor of claim 13, wherein a rounded surface connects the narrow throat and the wide throat.

18. The transistor of claim 13, wherein a non-linear surface connects the narrow throat and the wide throat.

19. A method of forming a semiconductor integrated circuit (IC) device comprising:
forming an inner spacer directly upon an active nanolayer;
after forming the inner spacer, indenting the active nanolayer and exposing an external corner region of the inner spacer; and
recessing the external corner region of the inner spacer to form a funneling inner spacer.

20. The method of claim 19, further comprising:
forming a source/drain (S/D) region directly upon the funneling inner spacer.
